(19) United States
(12) Patent Application Publication
(10) Pub. No.: US 2026/0032817 A1
(43) Pub. Date: Jan. 29, 2026

(54) VIA LOSS CONTROL IN A PRINTED CIRCUIT BOARD

(71) Applicant: DELL PRODUCTS L.P., Round Rock, TX (US)

(72) Inventors: Chang-Hsien Chen, New Taipei City (TW); Yi-Tang Chen, Xinzhuang (TW); Pei-Ju Lin, Taoyuan District (TW); Bhyrav Mutnury, Round Rock, TX (US)

(21) Appl. No.: 18/786,078

(22) Filed: Jul. 26, 2024

(51) Int. Cl. H05K 1/11; H05K 1/02; H05K 3/00; H05K 3/42

(52) U.S. Cl. CPC H05K 1/115; H05K 1/0216; H05K 3/0047; H05K 3/425; H05K 2201/09645

(57) ABSTRACT

A printed circuit board includes top and bottom surface, multiple layers, a via, a high loss tangent material, and a conductive material. The via extends from the top surface through the layers to the bottom surface. The high loss tangent material is located within the via and dissipates reflections in a signal propagated along the via. The conductive material is plated along the high loss tangent material and includes a roughened surface. The roughened surface dampens the reflections in the signal propagated along the via.

### FIELD OF THE DISCLOSURE

The present disclosure generally relates to information handling systems, and more particularly relates to controlling via loss in a printed circuit board.

### BACKGROUND

As the value and use of information continues to increase, individuals and businesses seek additional ways to process and store information. One option is an information handling system. An information handling system generally processes, compiles, stores, or communicates information or data for business, personal, or other purposes. Technology and information handling needs and requirements can vary between different applications. Thus, information handling systems can also vary regarding what information is handled, how the information is handled, how much information is processed, stored, or communicated, and how quickly and efficiently the information can be processed, stored, or communicated. The variations in information handling systems allow information handling systems to be general or configured for a specific user or specific use such as financial transaction processing, airline reservations, enterprise data storage, or global communications. In addition, information handling systems can include a variety of hardware and software resources that can be configured to process, store, and communicate information and can include one or more computer systems, graphics interface systems, data storage systems, networking systems, and mobile communication systems. Information handling systems can also implement various virtualized architectures. Data and voice communications among information handling systems may be via networks that are wired, wireless, or some combination.

### SUMMARY

A printed circuit board includes top and bottom surface, multiple layers, a via, a high loss tangent material, and a conductive material. The via may extend from the top surface through the layers to the bottom surface. The high loss tangent material may be located within the via and dissipate reflections in a signal propagated along the via. The conductive material is plated along the high loss tangent material and includes a roughened surface. The roughened surface may dampen the reflections in the signal propagated along the via.

### BRIEF DESCRIPTION OF THE DRAWINGS

It will be appreciated that for simplicity and clarity of illustration, elements illustrated in the Figures are not necessarily drawn to scale. For example, the dimensions of some elements may be exaggerated relative to other elements. Embodiments incorporating teachings of the present disclosure are shown and described with respect to the drawings herein, in which:

FIGS. 1-4 are diagrams of different steps in the creation of via loss control in a printed circuit board according to at least one embodiment of the present disclosure;

FIG. 5 is a diagram of two vias having loss control according to at least one embodiment of the present disclosure;

FIG. 6 is a cross-sectional view of two vias according to at least one embodiment of the present disclosure;

FIG. 7 is a diagram of conductive material for a via according to at least one embodiment of the present disclosure;

FIG. 8 is a flow diagram of a method for controlling via loss in a printed circuit board according to at least one embodiment of the present disclosure; and

FIG. 9 is a block diagram of a general information handling system according to an embodiment of the present disclosure.

The use of the same reference symbols in different drawings indicates similar or identical items.

### DETAILED DESCRIPTION OF THE DRAWINGS

The following description in combination with the Figures is provided to assist in understanding the teachings disclosed herein. The description is focused on specific implementations and embodiments of the teachings and is provided to assist in describing the teachings. This focus should not be interpreted as a limitation on the scope or applicability of the teachings.

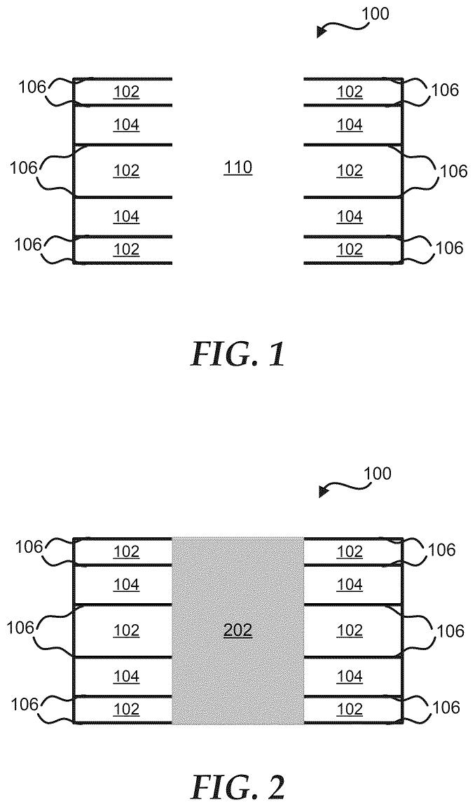

FIGS. 1-4 illustrate a portion of a printed circuit board 100 for an information handling system, such as information handling system 1000 in FIG. 10, according to at least one embodiment of the present disclosure. For purposes of this disclosure, an information handling system can include any instrumentality or aggregate of instrumentalities operable to compute, calculate, determine, classify, process, transmit, receive, retrieve, originate, switch, store, display, communicate, manifest, detect, record, reproduce, handle, or utilize any form of information, intelligence, or data for business, scientific, control, or other purposes. For example, an information handling system may be a personal computer (such as a desktop or laptop), tablet computer, mobile device (such as a personal digital assistant (PDA) or smart phone), server (such as a blade server or rack server), a network storage device, or any other suitable device and may vary in size, shape, performance, functionality, and price. The information handling system may include random access memory (RAM), one or more processing resources such as a central processing unit (CPU) or hardware or software control logic, ROM, and/or other types of nonvolatile memory. Additional components of the information handling system may include one or more disk drives, one or more network ports for communicating with external devices as well as various input and output (I/O) devices, such as a keyboard, a mouse, touchscreen and/or a video display. The information handling system may also include one or more buses operable to transmit communications between the various hardware components.

Printed circuit board 100 includes multiple core layers 102, multiple pre-impregnated layers 104, and multiple metal or conductor layers 106. In an example, the layers of printed circuit board 100 may vary among core layers 102, pre-impregnated layers 104, and metal layers 106. Each of core layers 102 may be a substrate or laminate of non-conducting material layer. Each of pre-impregnated layers 104 may be composited of fiberglass fabric impregnated with resin. Fabricating a printed circuit board, such as creating vias in the printed circuit board, is known in the art and will not be further disclosed herein, except as needed to illustrate the various embodiments of the present disclosure. Printed circuit board 100 may include additional components without varying from the scope of this disclosure.

Referring to FIG. 1, a via 110 may be drilled into and through layers 102, 104, and 106 of printed circuit board 100. This via 110 may be plated with a conductive plating, such as copper, to physically and electrically connect one or more layers 106 within printed circuit board 100 with one another and/or with a trace on a surface of the printed circuit board. In certain examples, a signal may be propagated along the trace, the conductive material within via 110, and layer 106. In an example, as the frequencies increase for the signal, unused portions of the plating on via 110 may act like transmission lines and resonate at quarter wavelength. This response within via 110 may result in reflections, which in turn may impact channel insertion loss.

Input/output (IO) signaling speeds may reach or exceed 64 Gbps to 128 Gbps, making via stub resonance a big challenge in printed circuit boards. In this situation, the signaling speeds may result in a via stub having huge impact on signal integrity. Based on the signal integrity issues caused by the reflections of the via stubs, via stub tolerances may need to be less than 10 mils. In certain examples, via stub resonances may be dampened as described herein to prevent or lessen signal integrity impacts on high-speed signals within via 110.

Referring to FIG. 2, the via may be filled with any suitable high loss material 202. In an example, material may be a high loss tangent material by a dissipation factor that is greater than a threshold. For example, the dissipation factor for material 202 may be greater than 0.04. In certain examples, the high loss tangent material may increase signal dissipation, which in turn may reduce signal reflections in via stubs as will be described below.

Referring to FIG. 3, a via 302 may be drilled into and through high loss tangent material 202. In an example, via 302 may be drilled with rough drill with tooth texture. In this example, the tooth texture of the rough drill may create indents or notches within high loss tangent material 202. In certain examples, the indents or notches created by the tooth texture of the rough drill may be in any suitable pattern, in no recognizable or detectable pattern, or the like. In an example, the diameter of the rough drill may be selected to enable a particular amount of high loss tangent material 202 to be left after via 302 is drilled. The thickness of high loss tangent material 202 may be greater than a threshold amount. For example, the thickness of high loss tangent material 202 may be greater than 3 mils, 3.5 mils, 4 mils or the like. One of ordinary skill in the art would recognize that mil is a unit of measurement utilized in routing on PCBs, and one mil equals one-thousandth of an inch or two hundred fifty-four ten-thousandths of a millimeter.

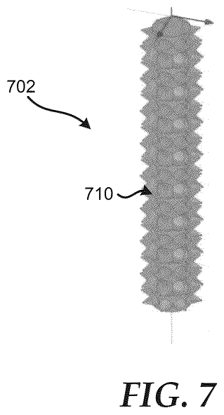

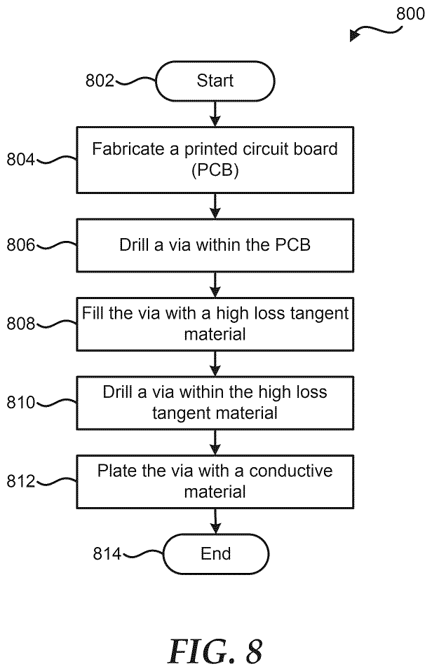

Referring to FIG. 4, after via 302 is formed within high loss tangent material 202 of printed circuit board 100, the via may be plating with a conductive material 402. In an example, conductive material 402 may be any suitable material including, but not limited to, copper and silver. The thickness of conductive material 402 may be within any suitable range, such as from 1 mil to 2 mils. Roughened conductive material 402 may include multiple nodules as illustrated in FIGS. 7 and 8 below. In certain examples, the nodules may be in any suitable pattern, in no recognizable or detectable pattern, or the like. The roughened nodules on conductive material 402 may cause a higher signal loss along the via as compared to a smooth conductive material. In an example, the roughened nodules on conductive material 402 may reduce reflections within via stubs, which in turn may improve signal integrity of high-speed signals transmitted along the conductive material.

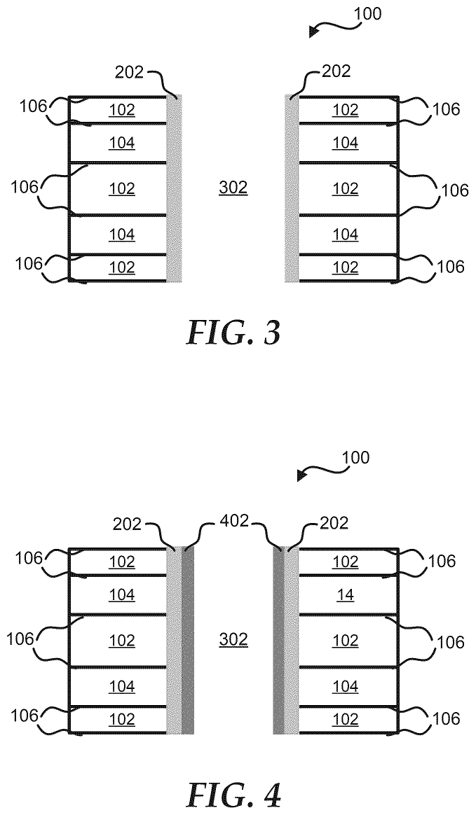

FIG. 5 illustrates vias 502 and 504 having loss control according to at least one embodiment of the present disclosure. Via 502 includes a top section 510, a bottom section 512, a layer connection section 514, and traces 516 and 518. Via 504 includes a top section 520, a bottom section 522, a layer connection section 524, and traces 526 and 528. Vias 502 and 504 may include additional features without varying from the scope of this disclosure.

In an example, top sections 510 and 520 may be located on a top surface of a printed circuit board, such as printed circuit board 100 of FIGS. 1-4. While top sections 510 and 520 are illustrated as a solid circular disc, the shapes of the top sections may vary without varying from the scope of this disclosure. For example, top sections 510 and 520 may not be solid such that a via hole may be visible in the center of each of the top sections. In certain examples, traces 516 and 526 may be physically and electrically connected to top sections 510 and 520. Traces 516 and 526 may be routed along the top surface of a printed circuit board, such as printed circuit board 100 of FIGS. 1-4.

In an example, bottom sections 512 and 522 may be located on a bottom surface of a printed circuit board, such as printed circuit board 100 of FIGS. 1-4. Bottom sections 512 and 522 may be designed substantially similar to top sections 510 and 522 such that they may not be solid such that a via hole may be visible in the center of each of the bottom sections. In certain examples, layer connection sections 514 and 524 may be located within any layer of a printed circuit board, such as printed circuit board 100 of FIGS. 1-4. Traces 518 and 528 may be physically and electrically connected to layer connection sections 514 and 524. Traces 518 and 528 may be routed along a layer of a printed circuit board, such as printed circuit board 100 of FIGS. 1-4.

Via 502 may propagate a signal from trace 516 to trace 518. However, the portion of via 502 that extends from layer connection section 514 to bottom section 512 may be a stub with respect to signals traveling from trace 516 to trace 518. As illustrated in FIG. 5, via 502 may include roughened areas 530 the entire length of the via. In an example, roughened areas 530 may reduce reflections from the via stub that extends from layer connection section 514 to bottom section 512. This reduction in a signal reflection may improve signal integrity of high-speed signals transmitted along the conductive material of via 502 from trace 516 to trace 518.

Via 504 may propagate a signal from trace 526 to trace 528. However, the portion of via 504 that extends from layer connection section 524 to bottom section 522 may be a stub with respect to signals traveling from trace 526 to trace 528. As illustrated in FIG. 5, via 504 may include roughened areas 540 the entire length of the via. In an example, roughened areas 540 may reduce reflections from the via stub that extends from layer connection section 524 to bottom section 522. This reduction in signal reflection may improve signal integrity of high-speed signals transmitted along the conductive material of via 504 from trace 526 to trace 528.

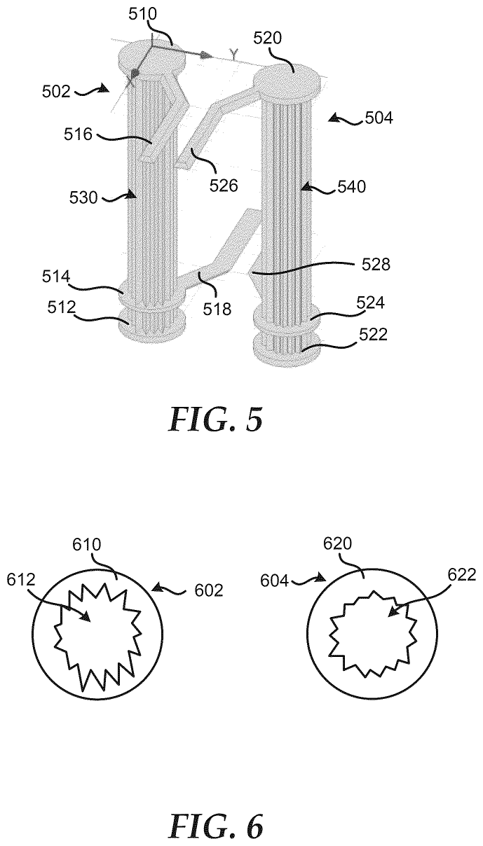

FIG. 6 illustrates a cross section of vias 602 and 604 according to at least one embodiment of the present disclosure. Via 602 includes a high loss tangent material 610 and a roughened pattern 612. Similarly, via 604 includes a high loss tangent material 620 and a roughened pattern 622. Vias 602 and 604 may include additional features without varying from the scope of this disclosure. For example, vias 602 and 604 may include conductive material within corresponding roughened patterns 612 and 622.

As illustrated in FIG. 6, high loss tangent material 610 of via 602 may have a particular thickness, which in turn may reduce signal reflections and improve signal integrity of high-speed signals transmitted along via 602. Roughened pattern 612 may be drilled out of high loss tangent material 610 so that a conductive material plated within via 602 may have roughened portions or patterns to create additional signal loss along via 602.

High loss tangent material 620 of via 604 may have a particular thickness, which in turn may reduce signal reflections and improve signal integrity of high-speed signals transmitted along via 604. Roughened pattern 622 may be drilled out of high loss tangent material 620 so that a conductive material plated within via 604 may have roughened portions or patterns to create additional signal loss along via 604.

FIG. 7 illustrates a conductive material 702 for a via, such as via 110 of FIG. 1, according to at least one embodiment of the present disclosure. Conductive material 702 includes a roughened pattern 710. While conductive material 702 is illustrated as being solid, the conductive material may be a plating within a via, such that a hole is located within the center of the conductive material without varying from the scope of this disclosure.

In an example, roughened pattern 710 may reduce reflections from a via stub that extends beyond a particular layer of a printed circuit board, such as a layer 106 of printed circuit board 100 of FIG. 1. This reduction in a signal reflection may improve signal integrity of high-speed signals transmitted along the conductive material 702 of the via.

FIG. 8 shows a method 800 for controlling via loss in a printed circuit board according to at least one embodiment of the present disclosure, starting at block 802. It will be readily appreciated that not every method step set forth in this flow diagram is always necessary, and that certain steps of the methods may be combined, performed simultaneously, in a different order, or perhaps omitted, without varying from the scope of the disclosure. FIG. 8 may be employed in whole, or in part, by any suitable type of controller, device, module, processor, or any combination thereof, operable to employ all, or portions of, the method of FIG. 8.

At block 804, a printed circuit board is fabricated. In an example, the printed circuit board may include multiple core layers, multiple pre-impregnated layers, and multiple metal or conductor layers. In an example, the layers of the printed circuit board may vary among core layers, pre-impregnated layers, and metal layers. At block 806, a via is drilled within the printed circuit board. In an example, the via may have substantially smooth edges.

At block 808, the via is filled with a high loss tangent material. In an example, material may be a high loss tangent material by a dissipation factor that is greater than a threshold. For example, the dissipation factor for the high loss tangent material may be greater than 0.04. At block 810, a via is drilled within the high loss tangent material. In an example, the via within the high loss tangent material may be drilled with rough drill with tooth texture. In this example, the tooth texture of the rough drill may create indents or notches within high loss tangent material. In certain examples, the indents or notches created by the tooth texture of the rough drill may be in any suitable pattern, in no recognizable or detectable pattern, or the like. In an example, the diameter of the rough drill may be selected to enable a particular amount of high loss tangent material to be left after via is drilled. For example, the thickness of high loss tangent material may be 3 mils, 3.5 mils, 4 mils or the like.

At block 812, the via is plating with a conductive material and the flow ends at block 814. In an example, the conductive material may be any suitable material including, but not limited to, copper and silver. The thickness of the conductive material may be any suitable thickness, such as 1 mil, 1.5 mils, 2 mils, or the like. One surface of conductive material may be roughened and include multiple nodules, and the opposite surface of the conductive material may be smooth. In an example, the roughened surface may be created based on the conductive material filling the notches within the high loss tangent material. In certain examples, the nodules may be in any suitable pattern, in no recognizable or detectable pattern, or the like. The roughened nodules on conductive material may cause a higher signal loss along the via as compared to a conductive material that is smooth on both surfaces. In an example, the roughened nodules on the conductive material may reduce reflections within via stubs, which in turn may improve signal integrity of high-speed signals transmitted along the conductive material.

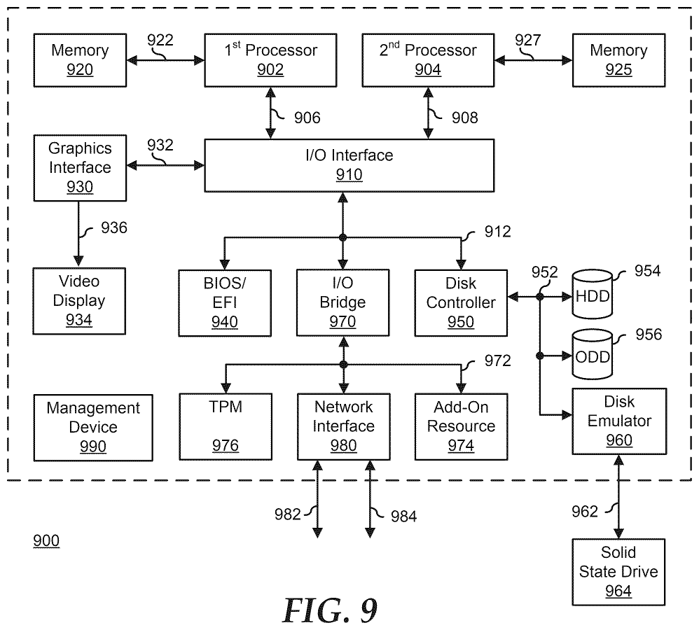

FIG. 9 shows a generalized embodiment of an information handling system 900 according to an embodiment of the present disclosure. For purpose of this disclosure an information handling system can include any instrumentality or aggregate of instrumentalities operable to compute, classify, process, transmit, receive, retrieve, originate, switch, store, display, manifest, detect, record, reproduce, handle, or utilize any form of information, intelligence, or data for business, scientific, control, entertainment, or other purposes. For example, information handling system 900 can be a personal computer, a laptop computer, a smart phone, a tablet device or other consumer electronic device, a network server, a network storage device, a switch router or other network communication device, or any other suitable device and may vary in size, shape, performance, functionality, and price. Further, information handling system 900 can include processing resources for executing machine-executable code, such as a central processing unit (CPU), a programmable logic array (PLA), an embedded device such as a System-on-a-Chip (SoC), or other control logic hardware. Information handling system 900 can also include one or more computer-readable medium for storing machine-executable code, such as software or data. Additional components of information handling system 900 can include one or more storage devices that can store machine-executable code, one or more communications ports for communicating with external devices, and various input and output (I/O) devices, such as a keyboard, a mouse, and a video display. Information handling system 900 can also include one or more buses operable to transmit information between the various hardware components.

Information handling system 900 can include devices or modules that embody one or more of the devices or modules described below and operates to perform one or more of the methods described below. Information handling system 900 includes a processors 902 and 904, an input/output (I/O) interface 910, memories 920 and 925, a graphics interface 930, a basic input and output system/universal extensible firmware interface (BIOS/UEFI) module 940, a disk controller 950, a hard disk drive (HDD) 954, an optical disk drive (ODD) 956, a disk emulator 960 connected to an external solid state drive (SSD) 964, an I/O bridge 970, one or more add-on resources 974, a trusted platform module (TPM) 976, a network interface 980, a management device 990, and a power supply 995. Processors 902 and 904, I/O interface 910, memory 920, graphics interface 930, BIOS/UEFI module 940, disk controller 950, HDD 954, ODD 956, disk emulator 960, SSD 964, I/O bridge 970, add-on resources 974, TPM 976, and network interface 980 operate together to provide a host environment of information handling system 900 that operates to provide the data processing functionality of the information handling system. The host environment operates to execute machine-executable code, including platform BIOS/UEFI code, device firmware, operating system code, applications, programs, and the like, to perform the data processing tasks associated with information handling system 900.

In the host environment, processor 902 is connected to I/O interface 910 via processor interface 906, and processor 904 is connected to the I/O interface via processor interface 908. Memory 920 is connected to processor 902 via a memory interface 922. Memory 925 is connected to processor 904 via a memory interface 927. Graphics interface 930 is connected to I/O interface 910 via a graphics interface 932 and provides a video display output 936 to a video display 934. In a particular embodiment, information handling system 900 includes separate memories that are dedicated to each of processors 902 and 904 via separate memory interfaces. An example of memories 920 and 930 include random access memory (RAM) such as static RAM (SRAM), dynamic RAM (DRAM), non-volatile RAM (NV-RAM), or the like, read only memory (ROM), another type of memory, or a combination thereof.

BIOS/UEFI module 940, disk controller 950, and I/O bridge 970 are connected to I/O interface 910 via an I/O channel 912. An example of I/O channel 912 includes a Peripheral Component Interconnect (PCI) interface, a PCI-Extended (PCI-X) interface, a high-speed PCI-Express (PCIe) interface, another industry standard or proprietary communication interface, or a combination thereof. I/O interface 910 can also include one or more other I/O interfaces, including an Industry Standard Architecture (ISA) interface, a Small Computer Serial Interface (SCSI) interface, an Inter-Integrated Circuit (I2C) interface, a System Packet Interface (SPI), a Universal Serial Bus (USB), another interface, or a combination thereof. BIOS/UEFI module 940 includes BIOS/UEFI code operable to detect resources within information handling system 900, to provide drivers for the resources, initialize the resources, and access the resources. BIOS/UEFI module 940 includes code that operates to detect resources within information handling system 900, to provide drivers for the resources, to initialize the resources, and to access the resources.

Disk controller 950 includes a disk interface 952 that connects the disk controller to HDD 954, to ODD 956, and to disk emulator 960. An example of disk interface 952 includes an Integrated Drive Electronics (IDE) interface, an Advanced Technology Attachment (ATA) such as a parallel ATA (PATA) interface or a serial ATA (SATA) interface, a SCSI interface, a USB interface, a proprietary interface, or a combination thereof. Disk emulator 960 permits SSD 964 to be connected to information handling system 900 via an external interface 962. An example of external interface 962 includes a USB interface, an IEEE 4394 (Firewire) interface, a proprietary interface, or a combination thereof. Alternatively, solid-state drive 964 can be disposed within information handling system 900.

I/O bridge 970 includes a peripheral interface 972 that connects the I/O bridge to add-on resource 974, to TPM 976, and to network interface 980. Peripheral interface 972 can be the same type of interface as I/O channel 912 or can be a different type of interface. As such, I/O bridge 970 extends the capacity of I/O channel 912 when peripheral interface 972 and the I/O channel are of the same type, and the I/O bridge translates information from a format suitable to the I/O channel to a format suitable to the peripheral channel 972 when they are of a different type. Add-on resource 974 can include a data storage system, an additional graphics interface, a network interface card (NIC), a sound/video processing card, another add-on resource, or a combination thereof. Add-on resource 974 can be on a main circuit board, on separate circuit board or add-in card disposed within information handling system 900, a device that is external to the information handling system, or a combination thereof.

Network interface 980 represents a NIC disposed within information handling system 900, on a main circuit board of the information handling system, integrated onto another component such as I/O interface 910, in another suitable location, or a combination thereof. Network interface device 980 includes network channels 982 and 984 that provide interfaces to devices that are external to information handling system 900. In a particular embodiment, network channels 982 and 984 are of a different type than peripheral channel 972 and network interface 980 translates information from a format suitable to the peripheral channel to a format suitable to external devices. An example of network channels 982 and 984 includes InfiniBand channels, Fibre Channel channels, Gigabit Ethernet channels, proprietary channel architectures, or a combination thereof. Network channels 982 and 984 can be connected to external network resources (not illustrated). The network resource can include another information handling system, a data storage system, another network, a grid management system, another suitable resource, or a combination thereof.

Management device 990 represents one or more processing devices, such as a dedicated baseboard management controller (BMC) System-on-a-Chip (SoC) device, one or more associated memory devices, one or more network interface devices, a complex programmable logic device (CPLD), and the like, which operate together to provide the management environment for information handling system 900. In particular, management device 990 is connected to various components of the host environment via various internal communication interfaces, such as a Low Pin Count (LPC) interface, an Inter-Integrated-Circuit (I2C) interface, a PCIe interface, or the like, to provide an out-of-band (OOB) mechanism to retrieve information related to the operation of the host environment, to provide BIOS/UEFI or system firmware updates, to manage non-processing components of information handling system 900, such as system cooling fans and power supplies. Management device 990 can include a network connection to an external management system, and the management device can communicate with the management system to report status information for information handling system 900, to receive BIOS/UEFI or system firmware updates, or to perform other task for managing and controlling the operation of information handling system 900.

Management device 990 can operate off of a separate power plane from the components of the host environment so that the management device receives power to manage information handling system 900 when the information handling system is otherwise shut down. An example of management device 990 include a commercially available BMC product or other device that operates in accordance with an Intelligent Platform Management Initiative (IPMI) specification, a Web Services Management (WSMan) interface, a Redfish Application Programming Interface (API), another Distributed Management Task Force (DMTF), or other management standard, and can include an Integrated Dell Remote Access Controller (iDRAC), an Embedded Controller (EC), or the like. Management device 990 may further include associated memory devices, logic devices, security devices, or the like, as needed, or desired.

Although only a few exemplary embodiments have been described in detail herein, those skilled in the art will readily appreciate that many modifications are possible in the exemplary embodiments without materially departing from the novel teachings and advantages of the embodiments of the present disclosure. Accordingly, all such modifications are intended to be included within the scope of the embodiments of the present disclosure as defined in the following claims. In the claims, means-plus-function clauses are intended to cover the structures described herein as performing the recited function and not only structural equivalents, but also equivalent structures.

What is claimed is:

1. A printed circuit board comprising:
top and bottom surfaces;
multiple layers;
a via extending from the top surface through the layers to the bottom surface;
a high loss tangent material within the via, wherein the high loss tangent material dissipates reflections in a signal propagated along the via; and
a conductive material plated along the high loss tangent material, the conductive material includes a roughened surface, the roughened surface dampening the reflections in the signal propagated along the via.

2. The printed circuit board of claim 1, wherein the high loss tangent material includes: an inner surface having multiple notches cut within the inner surface.

3. The printed circuit board of claim 2, wherein the multiple notches are cut when a hole is drilled within the high loss tangent material.

4. The printed circuit board of claim 2, wherein the roughened surface of the conductive material is formed from portions of the conductive material filling the multiple notches within the inner surface of the high loss tangent material.

5. The printed circuit board of claim 1, wherein the high loss tangent material has a first thickness that is greater than a threshold amount.

6. The printed circuit board of claim 5, wherein the conductive material has a second thickness that is within a particular range of thickness.

7. The printed circuit board of claim 6, wherein the first thickness is greater than the second thickness.

8. The printed circuit board of claim 1, wherein the conductive material includes a smooth surface that is opposite to the roughened surface.

9. The printed circuit board of claim 1, wherein the high loss tangent material includes a smooth surface that is adjacent to the multiple layers.

10. A method comprising:
fabricating a printed circuit board, wherein the printed circuit board includes top and bottom surfaces and multiple layers;
drilling a first via within the printed circuit board, wherein the first via extends from the top surface through the layers to the bottom surface;
filling the first via with a high loss tangent material, wherein the high loss tangent material dissipates reflections in a signal;
drilling a second via within the high loss tangent material; and
plating the second via with a conductive material, wherein the conductive material includes a roughened surface, the roughened surface dampening the reflections in the signal propagated along the conductive material.

11. The method of claim 10, wherein the high loss tangent material includes: an inner surface having multiple notches cut within the inner surface.

12. The method of claim 11, wherein the multiple notches are cut when a hole is drilled within the high loss tangent material.

13. The method of claim 11, wherein the roughened surface of the conductive material is formed from portions of the conductive material filling the multiple notches within the inner surface of the high loss tangent material.

14. The method of claim 10, wherein the high loss tangent material has a first thickness that is greater than a threshold amount.

15. The method of claim 14, wherein the conductive material has a second thickness that is within a particular range of thickness.

16. The method of claim 15, wherein the first thickness is greater than the second thickness.

17. The method of claim 10, wherein the conductive material includes a smooth surface that is opposite to the roughened surface.

18. The method of claim 10, wherein the high loss tangent material includes a smooth surface that is adjacent to the multiple layers.

19. A printed circuit board comprising:
top and bottom surfaces;
multiple layers;
a via extending from the top surface through the layers to the bottom surface;
a high loss tangent material within the via, the high loss tangent material including multiple notches cut within an inner surface and includes a smooth outer surface that is adjacent to the multiple layers, wherein the high loss tangent material dissipates reflections in a signal propagated along the via; and
a conductive material plated along the high loss tangent material, the conductive material including a roughened surface, wherein the roughened surface of the conductive material is formed from portions of the conductive material filling the multiple notches within the inner surface of the high loss tangent material, the roughened surface dampening the reflections in the signal propagated along the via.

20. The printed circuit board of claim 19, wherein the conductive material includes a smooth surface that is opposite to the roughened surface.
